(19) United States
(12) Patent Application Publication
(10) Pub. No.: US 2024/0194618 A1
(43) Pub. Date: Jun. 13, 2024

(54) SEMICONDUCTOR PACKAGE

(71) Applicant: Electronics and Telecommunications Research Institute, Daejeon (KR)

(72) Inventors: HUI DONG LEE, Daejeon (KR); Sunwoo KONG, Daejeon (KR); Bong Hyuk PARK, Daejeon (KR); SEUNG HUN WANG, Daejeon (KR); Seunghyun JANG, Daejeon (KR); SEOK BONG HYUN, Daejeon (KR)

(73) Assignee: Electronics and Telecommunications Research Institute, Daejeon (KR)

(21) Appl. No.: 18/349,024

(22) Filed: Jul. 7, 2023

(30) Foreign Application Priority Data
Dec. 9, 2022 (KR) 10-2022-0171264

(51) Int. Cl. H01L 23/66; H01L 23/00; H01L 23/495; H01L 23/64

(52) U.S. Cl. CPC H01L 23/66; H01L 23/4952; H01L 23/642; H01L 23/647; H01L 24/48; H01L 2223/6627; H01L 2224/48195

(57) ABSTRACT

A semiconductor package is provided. The semiconductor package includes a semiconductor chip including an integrated circuit (IC) pad configured to output a wireless frequency signal, a lead frame including a package pad configured to receive the wireless frequency signal, a first wire of which one end is connected to the IC pad, a second wire of which one end is connected to the package pad, and a circuit element connected to the first wire and the second wire in parallel or in series. A radio frequency (RF) output impedance of the package pad or an RF output impedance of the IC pad is controlled by a type of the circuit element or a connection relationship between the circuit element, the first wire, and the second wire.

### CROSS-REFERENCE TO RELATED APPLICATION

This application claims the benefit of Korean Patent Application No. 10-2022-0171264 filed on Dec. 9, 2022, in the Korean Intellectual Property Office, the entire disclosure of which is incorporated herein by reference for all purposes.

### BACKGROUND

### 1. Field of the Invention

One or more embodiments relate to a semiconductor package.

### 2. Description of the Related Art

A semiconductor device needs to be electrically packaged in a shape suitable for the semiconductor chip to be equipped in a required position as a component of a substrate or an electronic device. Packaging serves functions and roles such as interconnection, power supply, heat dissipation, semiconductor chip protection, and the like. Such packaging includes flat no-leads packaging. A flat no-leads package refers to a type of integrated circuit (IC) package having integrated pins for surface implementation and includes dual-flat no-leads (DFN) and quad-flat no-leads (QFN). Flat no-leads are often referred to as micro lead frames. Flat no-leads packages provide physical and electrical connections between encapsulated IC components and external circuitry such as a printed circuit board (PCB).

### SUMMARY

According to an aspect, there is provided a semiconductor package including an integrated circuit (IC) pad configured to output a wireless frequency signal, a lead frame including a package pad configured to receive the wireless frequency signal, a first wire of which one end is connected to the IC pad, a second wire of which one end is connected to the package pad, and a circuit element connected to the first wire and the second wire in parallel or in series. A radio frequency (RF) output impedance of the package pad or an RF output impedance of the IC pad may be controlled by a type of the circuit element or a connection relationship between the circuit element, the first to wire, and the second wire.

The circuit element may be a capacitor connected to the first wire and the second wire in parallel.

The circuit element may be a capacitor connected to the first wire and the second wire in series.

The circuit element may be a resistance element connected to the first wire and the second wire in parallel.

The circuit element may be a microstrip line connected to the first wire and the second wire in parallel.

The microstrip line may be connected to an equipotential terminal supplying a power supply voltage.

The microstrip line may not be connected to an equipotential terminal supplying a power supply voltage.

The circuit element may be a microstrip line connected to the first wire and the second wire in series.

According to an aspect, there is provided a semiconductor package including a semiconductor chip including an IC pad configured to output a wireless frequency signal, a lead frame including a package pad configured to receive the wireless frequency signal, a passive element placed between the IC pad and the package pad, a first wire of which one end is connected to the IC pad and the other end is connected to the passive element, and a second wire of which one end is connected to the package pad and the other end is connected to the passive element.

The passive element may be a capacitor connected to the first wire and the second wire in parallel.

The passive element may be a capacitor connected to the first wire and the second wire in series.

The passive element may be a resistance element connected to the first wire and the second wire in parallel.

The passive element may be a microstrip line connected to the first wire and the second wire in parallel.

The microstrip line may be connected to an equipotential terminal supplying a power supply voltage.

The microstrip line may not be connected to an equipotential terminal supplying a power supply voltage.

The passive element may be a microstrip line connected to the first wire and the second wire in series.

Additional aspects of embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a diagram illustrating an overview of a semiconductor package according to an embodiment;

FIG. 2A is a diagram illustrating a connection relationship between a package pad and an integrated circuit (IC) pad of a semiconductor package according to a first embodiment;

FIG. 2B is a diagram illustrating an equivalent circuit between the package pad and the IC pad of the semiconductor package according to the first embodiment;

FIG. 2C illustrates a Smith chart for describing an impedance from the viewpoint of the package pad of the semiconductor package according to the first embodiment;

FIG. 3A is a diagram illustrating a connection relationship between a package pad and an IC pad of a semiconductor package according to a second embodiment;

FIG. 3B is a diagram illustrating an equivalent circuit between the package pad and the IC pad of the semiconductor package according to the second embodiment;

FIG. 3C illustrates a Smith chart for describing an impedance from the viewpoint of the package pad of the semiconductor package according to the second embodiment;

FIG. 4A is a diagram illustrating a connection relationship between a package pad and an IC pad of a semiconductor package according to a third embodiment;

FIG. 4B is a diagram illustrating an equivalent circuit between the package pad and the IC pad of the semiconductor package according to the third embodiment;

FIG. 4C illustrates a Smith chart for describing an impedance from the viewpoint of the package pad of the semiconductor package according to the third embodiment;

FIG. 5A is a diagram illustrating a connection relationship between a package pad and an IC pad of a semiconductor package according to a fourth embodiment;

FIG. 5B is a diagram illustrating an equivalent circuit between the package pad and the IC pad of the semiconductor package according to the fourth embodiment;

FIG. 5C illustrates a Smith chart for describing an impedance from the viewpoint of the package pad of the semiconductor package according to the fourth embodiment;

FIG. 6A is a diagram illustrating a connection relationship between a package pad and an IC pad of a semiconductor package according to a fifth embodiment;

FIG. 6B is a diagram illustrating an equivalent circuit between the package pad and the IC pad of the semiconductor package according to the fifth embodiment;

FIG. 6C illustrates a Smith chart for describing an impedance from the viewpoint of the package pad of the semiconductor package according to the fifth embodiment;

FIG. 7A is a diagram illustrating a connection relationship between a package pad and an IC pad of a semiconductor package according to a sixth embodiment;

FIG. 7B is a diagram illustrating an equivalent circuit between the package pad and the IC pad of the semiconductor package according to the sixth embodiment; and

FIG. 7C illustrates a Smith chart for describing an impedance from the viewpoint of the package pad of the semiconductor package according to the sixth embodiment.

### DETAILED DESCRIPTION

The following structural or functional descriptions of embodiments described herein are merely intended for the purpose of describing the embodiments described herein and may be implemented in various forms. Thus, actual form of implementation is not limited to the embodiments described herein, and should be understood to include all changes, equivalents, and replacements within the idea and the technical scope of the disclosure.

Although terms of “first,” “second,” and the like are used to explain various components, the components are not limited to such terms. These terms are used only to distinguish one component from another component. For example, a first component may be referred to as a second component, and similarly, the second component may be referred to as the first component within the scope of the present disclosure.

When it is mentioned that one component is “connected” to another component, it may be understood that the one component is directly connected or coupled to another component or still another component is interposed between the two components.

As used herein, the singular forms “a,” “an,” and “the” are intended to include the plural forms as well, unless the context clearly indicates otherwise. As used herein, “A or B,” “at least one of A and B,” “at least one of A or B,” “A, B, or C,” “at least one of A, B, and C,” and “at least one of A, B, or C,” each of which may include any one of the items listed together in the corresponding one of the phrases, or all possible combinations thereof. It will be further understood that the terms “include,” “comprise,” and/or “comprising,” when used in this specification, specify the presence of stated features, integers, steps, operations, elements, components or a combination thereof, but do not preclude the presence or addition of one or more other features, integers, steps, operations, elements, components, and/or groups thereof.

Unless otherwise defined herein, all terms used herein including technical or scientific terms have the same meanings as those generally understood by one of ordinary skill in the art. Terms defined in dictionaries generally used should be construed to have meanings matching contextual meanings in the related art and are not to be construed as an ideal or excessively formal meaning unless otherwise defined herein.

Hereinafter, embodiments will be described in detail with reference to the accompanying drawings. When describing the embodiments with reference to the accompanying drawings, like reference numerals refer to like components and a repeated description related thereto will be omitted.

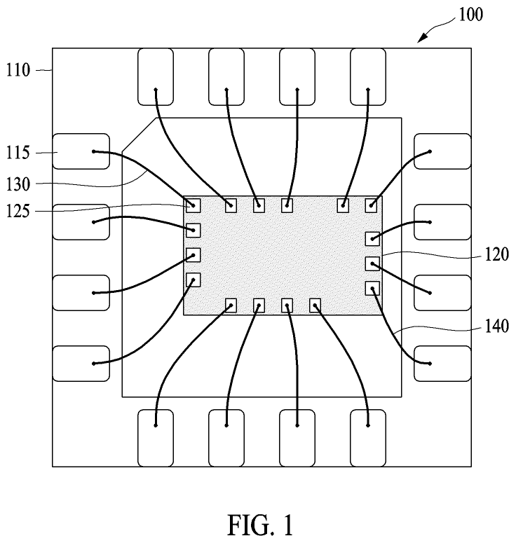

FIG. 1 is a diagram illustrating an overview of a semiconductor package according to an embodiment.

Referring to FIG. 1, a semiconductor package 100 may include a semiconductor chip 120 including an integrated circuit (IC) pad that is configured to output a wireless frequency signal, and a lead frame 110 including a package pad that is configured to receive the wireless frequency signal. The lead frame 110 may include a plurality of package pads 115, and the number of package pads 115 may vary depending on an embodiment. The semiconductor chip 120 may include a plurality of IC pads 125. The semiconductor package 100 may include a circuit element (or a passive element) placed between the IC pad 125 and the package pad 115.

The package pads 115 may be connected to the IC pads 125 through a wire-bonding method. The wire-bonding method may refer to physically connecting each of the package pads 115 and each of the IC pads 125 through wires, and the lengths of the wires may be different depending on the location of the placement of the semiconductor chip 120.

For example, a radio frequency (RF) signal may be transmitted from the lead frame 110 to the semiconductor chip 120 through a wire 130 and may be transmitted from the semiconductor chip 120 to the lead frame 110 through a wire 140. The lengths and thicknesses of the wire 130 and the wire 140 connected to different package pads and IC pads may be different. As the length of a wire increases, the impedance value of the wire may increase and as the thickness of the wire decreases, the impedance value of the wire may decrease.

The semiconductor package 100 may be a quad flat no-lead package. The quad flat no-lead package may be a semiconductor package in which the package pads 115 are placed on four sides of the lead frame 110 and the semiconductor chip 120 is implemented on the lead frame 110 without using a through hole.

When a semiconductor chip 120 is implemented on the lead frame 110 through a wire-bonding method, a parasitic component such as parasitic capacitance, parasitic inductance, or the like may be generated due to the wire. A parasitic component generated in a process of producing a semiconductor package through a wire-bonding method may be particularly severe when the operating frequency of the semiconductor package is high.

For a semiconductor package operating at a high frequency to operate efficiently, impedance matching of an input pad and an output pad is important. In general, an RF input impedance and an RF output impedance of a semiconductor package operating at a high frequency may be matched to “50” ohms. When the RF input impedance and the RF output impedance are not matched, signal reflection may occur, which may lead to deterioration of the quality of the semiconductor package.

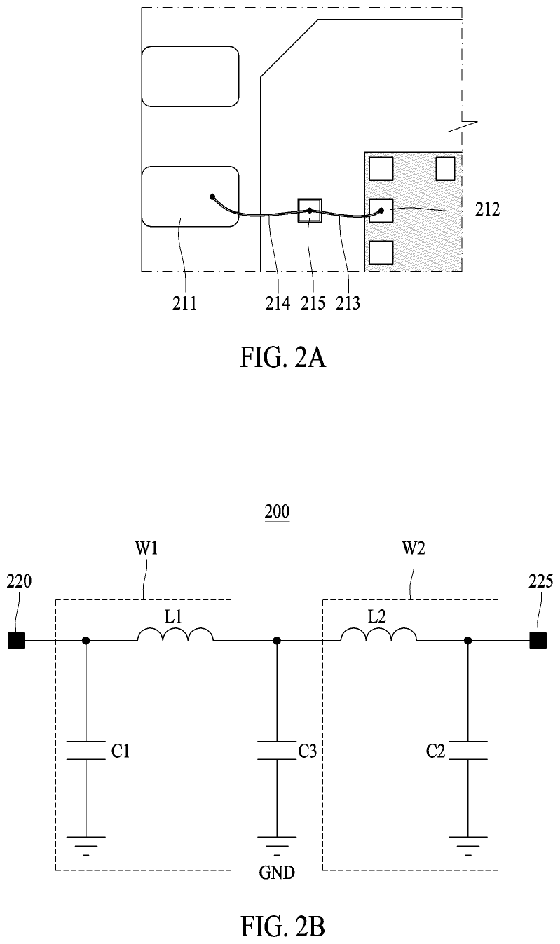

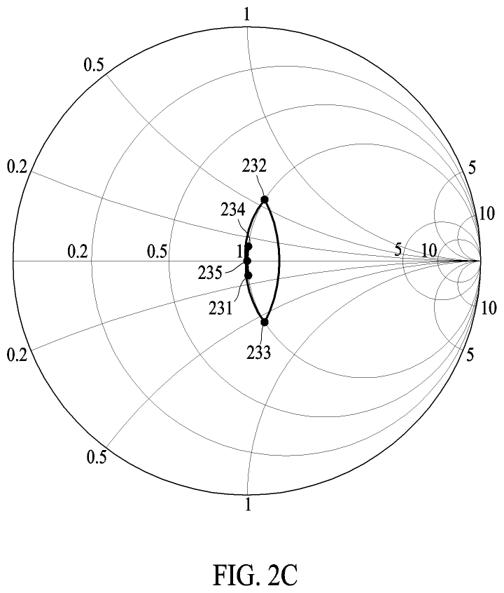

A parasitic component generated due to the wire-bonding method may affect the RF input impedance and the RF output impedance of a semiconductor package operating at a high frequency. According to the present disclosure, matching between the RF input impedance and the RF output impedance may be controlled through two wires and a circuit element or a passive element connected to the two wires, and the impedance value of the wire may be controlled by the length and thickness of the wire. A structure of a semiconductor package and a change of an impedance value according to an embodiment are described in detail below with reference to FIGS. 2A to 7C.

FIG. 2A is a diagram illustrating a connection relationship between a package pad and an IC pad of a semiconductor package according to a first embodiment.

FIG. 2A may be a diagram illustrating part of the semiconductor package 100 described above with reference to FIG. 1. Referring to FIG. 2A, a package pad 211 and an IC pad 212 may be connected through a first wire 213, a second wire 214, and a circuit element (or a passive element) 215. The circuit element 215 may be a capacitor that is connected to the first wire 213 and the second wire 214 in parallel. The circuit element 215 may be a single-layer capacitor. The circuit element 215 may be implemented in an empty space of a semiconductor package, and one end of the circuit element 215 may be connected to an equipotential terminal supplying a ground (GND) voltage.

One end of the first wire 213 may be connected to the IC pad 212 and the other end of the first wire 213 may be connected to the circuit element 215. One end of the second wire 214 may be connected to the package pad 211 and the other end of the second wire 214 may be connected to the circuit element 215. The first wire 213 and the second wire 214 may be configured as a dual wire-bonding according to an embodiment. When the first wire 213 or the second wire 214 is configured as a dual wire-bonding, the impedance value of a wire may decrease.

FIG. 2B is a diagram illustrating an equivalent circuit between the package pad and the IC pad of the semiconductor package according to the first embodiment.

FIG. 2B may be an equivalent circuit 200 showing a configuration between the package pad 211 and the IC pad 212 described with reference to FIG. 2A. Referring to FIG. 2B, the equivalent circuit 200 may include a first parasitic component model W1, a second parasitic component model W2, and a circuit element (e.g. capacitor C3). An IC pad 220 may correspond to the IC pad 212 of FIG. 2A, a package pad 225 may correspond to the package pad 211 of FIG. 2A, and the capacitor C3 may correspond to the circuit element 215 of FIG. 2A.

The first parasitic component model W1 may represent a parasitic component generated due to the first wire 213 of FIG. 2A. The first parasitic component model W1 may include a parasitic capacitance C1 and a parasitic inductor L1 that are connected to each other. The second parasitic component model W2 may represent a parasitic component generated due to the second wire 214 of FIG. 2A. The second parasitic component model W2 may include a parasitic capacitance C2 and a parasitic inductor L2 that are connected to each other.

An RF signal may be transmitted from the IC pad 220 to the package pad 225. As the RF signal is transmitted from the IC pad 220 to the package pad 225, an impedance value from the viewpoint of the package pad 225 may change. The change of the impedance value due to the transmission of the RF signal is described in detail with reference to FIG. 2C.

One end of the capacitor C3 may be connected to the parasitic inductor L1 and the parasitic inductor L2, and the other end of the capacitor C3 may be connected to an equipotential terminal supplying a power supply voltage. For example, the other end of the capacitor C3 may be connected to an equipotential terminal supplying a GND voltage.

FIG. 2C illustrates a Smith chart for describing an impedance from the viewpoint of the package pad of the semiconductor package according to the first embodiment.

FIG. 2C may be a diagram illustrating a Smith chart that shows a change of an impedance value due to the transmission of an RF signal on the circuit diagram of FIG. 2B, with a characteristic impedance value of “50” ohms. The impedance value at the center of the Smith chart may be “50” ohms. The characteristic impedance of a Smith chart may vary depending on an embodiment. Different locations on a Smith chart may represent different impedance values.

Referring to FIGS. 2B and 2C, an RF input impedance value at the IC pad 220 may be at the center circle of the Smith chart and match to “50” ohms. The impedance value at the center of the Smith chart may change into the impedance value at a first location 231 due to the parasitic capacitance C1. The impedance value at the first location 231 may change into the impedance value at a second location 232 due to the parasitic inductor L1. The impedance value at the second location 232 may change into the impedance value at a third location 233 due to the capacitor C3. The impedance value at the third location 233 may change into the impedance value at a fourth location 234 due to the parasitic inductor L2. The impedance value at the fourth location 234 may change into the impedance value at a fifth location 235 due to the parasitic capacitance C2.

The impedance value at the fifth location 235 may correspond to an RF output impedance value at the package pad 225. The impedance value at the fifth location 235 may be substantially the same as the RF input impedance value at the IC pad 220. Thus, the RF input impedance value at the IC pad 220 and the RF output impedance value at the package pad 225 may be substantially almost the same. Signal reflection due to the impedance difference between two connection terminals may be effectively reduced by matching the RF input impedance value at the IC pad 220 and the RF output impedance value at the package pad 225 to be substantially almost the same using the first wire W1, the second wire W2, and the capacitor C3.

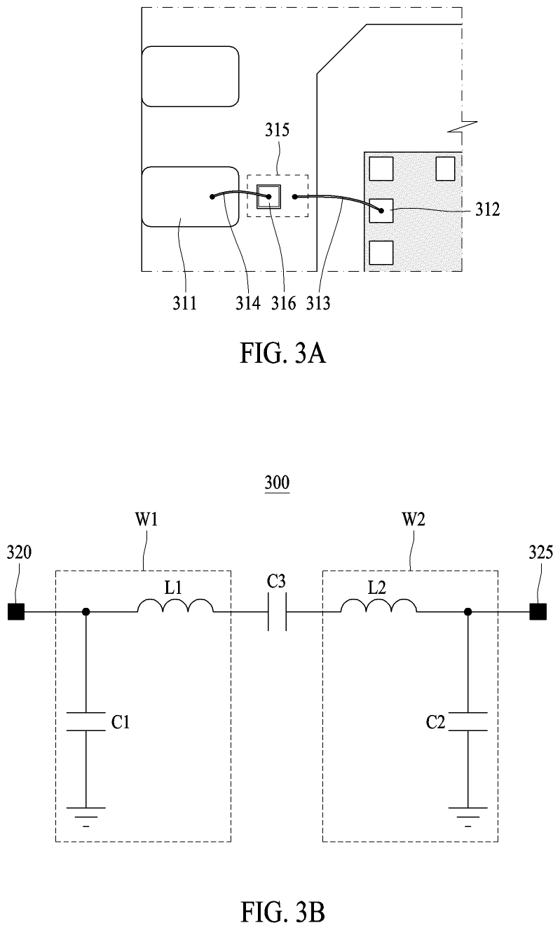

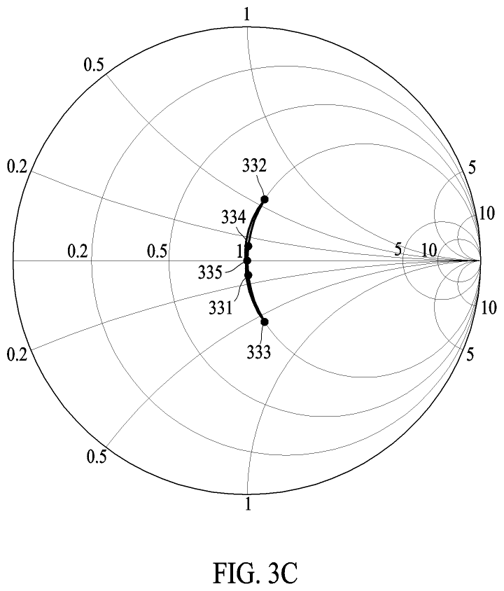

FIG. 3A is a diagram illustrating a connection relationship between a package pad and an IC pad of a semiconductor package according to a second embodiment.

FIG. 3A may be a diagram illustrating part of the semiconductor package 100 described above with reference to FIG. 1. Referring to FIG. 3A, a package pad 311 and an IC pad 312 may be connected through a first wire 313, a second wire 314, and a circuit element (or a passive element) 316. The circuit element 316 may be a capacitor that is connected to the first wire 313 and the second wire 314 in series. The circuit element 316 may be a single-layer capacitor. The circuit element 316 may be implemented on a land 315 that is in an empty space of a semiconductor package and that is electrically connected.

One end of the first wire 313 may be connected to the IC pad 312 and the other end of the first wire 313 may be connected to the land 315. One end of the second wire 314 may be connected to the package pad 311 and the other end of the second wire 314 may be connected to the circuit element 316.

FIG. 3B is a diagram illustrating an equivalent circuit between the package pad and the IC pad of the semiconductor package according to the second embodiment.

FIG. 3B may be an equivalent circuit 300 showing a configuration between the package pad 311 and the IC pad 312 described with reference to FIG. 3A. Referring to FIG. 3B, the equivalent circuit 300 may include the first parasitic component model W1, the second parasitic component model W2, and the capacitor C3. An IC pad 320 may correspond to the IC pad 312 of FIG. 3A, a package pad 325 may correspond to the package pad 311 of FIG. 3A, and the capacitor C3 may correspond to the circuit element 315 of FIG. 3A.

The first parasitic component model W1 may represent a parasitic component generated due to the first wire 313 of FIG. 3A. The first parasitic component model W1 may include a parasitic capacitance C1 and the parasitic inductor L1 that are connected to each other. The second parasitic component model W2 may represent a parasitic component generated due to the second wire 314 of FIG. 3A. The second parasitic component model W2 may include a parasitic capacitance C2 and the parasitic inductor L2 that are connected to each other. One end of the capacitor C3 may be connected to the parasitic inductor L1 and the other end of the capacitor C3 may be connected to the parasitic inductor L2.

An RF signal may be transmitted from the IC pad 320 to the package pad 325. As the RF signal is transmitted from the IC pad 320 to the package pad 325, an impedance value from the viewpoint of the package pad 325 may change. The change of the impedance value due to the transmission of the RF signal is described in detail with reference to FIG. 3C.

FIG. 3C illustrates a Smith chart for describing an impedance from the viewpoint of the package pad of the semiconductor package according to the second embodiment.

FIG. 3C may be a diagram illustrating a Smith chart that shows a change of an impedance value due to the transmission of an RF signal on the circuit diagram of FIG. 3B, with a characteristic impedance value of “50” ohms. Referring to FIGS. 3B and 3C, an RF input impedance value at the IC pad 320 may be at the center circle of the Smith chart and match to “50” ohms. The impedance value at the center of the Smith chart may change into the impedance value at a first location 331 due to the parasitic capacitance C1. The impedance value at the first location 331 may change into the impedance value at a second location 332 due to the parasitic inductor L1. The impedance value at the second location 332 may change into the impedance value at a third location 333 due to the capacitor C3. The impedance value at the third location 333 may change into the impedance value at a fourth location 334 due to the parasitic inductor L2. The impedance value at the fourth location 334 may change into the impedance value at a fifth location 335 due to the parasitic capacitance C2.

The impedance value at the fifth location 335 may correspond to an RF output impedance value at the package pad 325. The impedance value at the fifth location 335 may be substantially almost the same as the RF input impedance value at the IC pad 320. Thus, the RF input impedance value at the IC pad 320 and the RF output impedance value at the package pad 325 may be substantially almost the same.

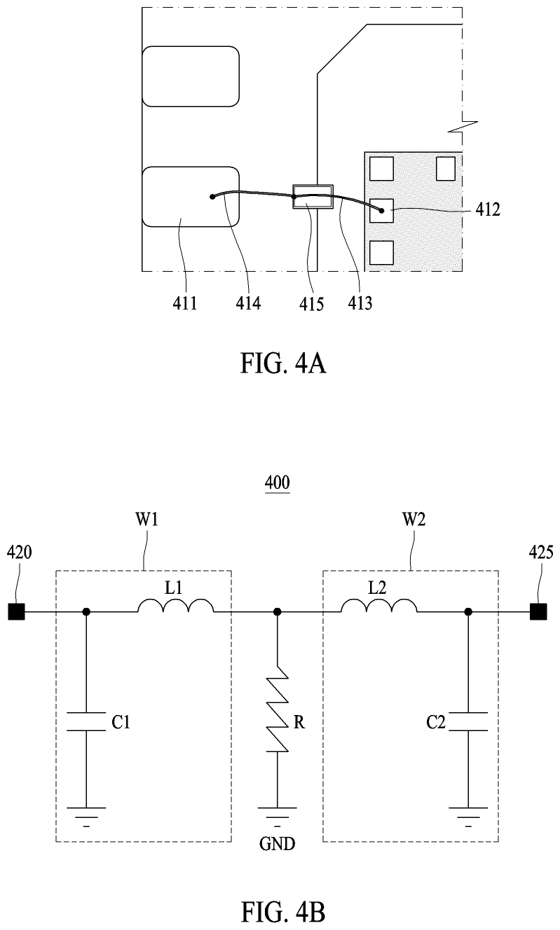

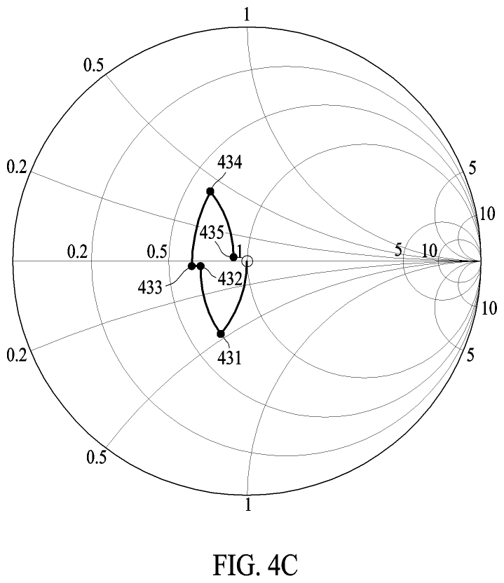

FIG. 4A is a diagram illustrating a connection relationship between a package pad and an IC pad of a semiconductor package according to a third embodiment.

FIG. 4A may be a diagram illustrating part of the semiconductor package 100 described above with reference to FIG. 1. Referring to FIG. 4A, a package pad 411 and an IC pad 412 may be connected through a first wire 413, a second wire 414, and a circuit element (or a passive element) 415. The circuit element 415 may be a resistance element that is connected to the first wire 413 and the second wire 414 in parallel. The circuit element 415 may be implemented in an empty space of a semiconductor package, and one end of the circuit element 415 may be connected to an equipotential terminal supplying a GND voltage.

One end of the first wire 413 may be connected to the IC pad 412 and the other end of the first wire 413 may be connected to the circuit element 415. One end of the second wire 414 may be connected to the package pad 411 and the other end of the second wire 414 may be connected to the circuit element 415.

FIG. 4B is a diagram illustrating an equivalent circuit between the package pad and the IC pad of the semiconductor package according to the third embodiment.

FIG. 4B may be an equivalent circuit 400 showing a configuration between the package pad 411 and the IC pad 412 described with reference to FIG. 4A. Referring to FIG. 4B, the equivalent circuit 400 may include the first parasitic component model W1, the second parasitic component model W2, and a resistance element R. An IC pad 420 may correspond to the IC pad 412 of FIG. 4A, a package pad 425 may correspond to the package pad 411 of FIG. 4A, and the resistance element R may correspond to the circuit element 415 of FIG. 4A.

The first parasitic component model W1 may represent a parasitic component generated due to the first wire 413 of FIG. 4A. The first parasitic component model W1 may include a parasitic capacitance C1 and the parasitic inductor L1 that are connected to each other. The second parasitic component model W2 may represent a parasitic component generated due to the second wire 414 of FIG. 4A. The second parasitic component model W2 may include a parasitic capacitance C2 and the parasitic inductor L2 that are connected to each other. One end of the resistance element R may be connected to the parasitic inductor L1 and the parasitic inductor L2 and the other end of the resistance element R may be connected to an equipotential terminal supplying a power supply voltage. For example, the other end of the resistance element R may be connected to an equipotential terminal supplying a GND voltage.

An RF signal may be transmitted from the IC pad 420 to the package pad 425. As the RF signal is transmitted from the IC pad 420 to the package pad 425, an impedance value from the viewpoint of the package pad 425 may change. The change of the impedance value due to the transmission of the RF signal is described in detail with reference to FIG. 4C.

FIG. 4C illustrates a Smith chart for describing an impedance from the viewpoint of the package pad of the semiconductor package according to the third embodiment.

FIG. 4C may be a diagram illustrating a Smith chart that shows a change of an impedance value due to the transmission of an RF signal on the circuit diagram of FIG. 4B, with a characteristic impedance value of “50” ohms. Referring to FIGS. 4B and 4C, an RF input impedance value at the IC pad 420 may be at the center circle of the Smith chart and match to “50” ohms. The impedance value at the center of the Smith chart may change into the impedance value at a first location 431 due to the parasitic capacitance C1. The impedance value at the first location 431 may change into the impedance value at a second location 432 due to the parasitic inductor L1. The impedance value at the second location 432 may change into the impedance value at a third location 433 due to the resistance element R. The impedance value at the third location 433 may change into the impedance value at a fourth location 434 due to the parasitic inductor L2. The impedance value at the fourth location 434 may change into the impedance value at a fifth location 435 due to the parasitic capacitance C2.

The impedance value at the fifth location 435 may correspond to an RF output impedance value at the package pad 425. The impedance value at the fifth location 435 may be substantially almost the same as the RF input impedance value at the IC pad 420. Thus, the RF input impedance value at the IC pad 420 and the RF output impedance value at the package pad 425 may be substantially the same.

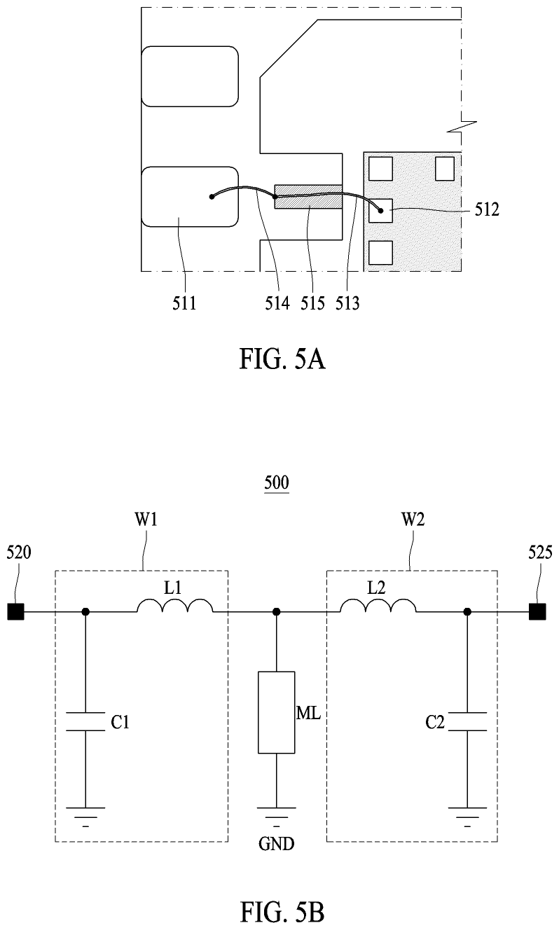

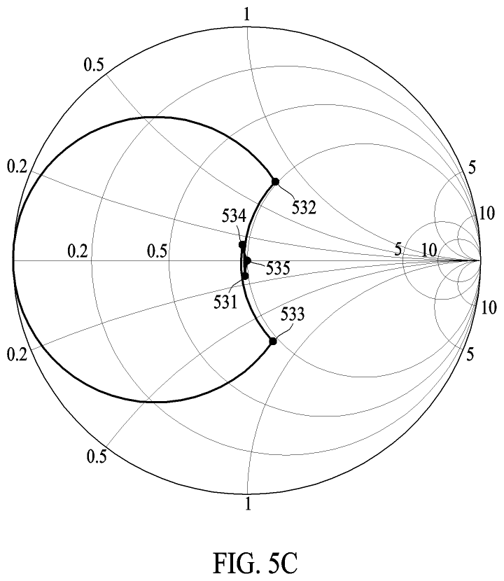

FIG. 5A is a diagram illustrating a connection relationship between a package pad and an IC pad of a semiconductor package according to a fourth embodiment.

FIG. 5A may be a diagram illustrating part of the semiconductor package 100 described above with reference to FIG. 1. Referring to FIG. 5A, a package pad 511 and an IC pad 512 may be connected through a first wire 513, a second wire 514, and a circuit element (or a passive element) 515. The circuit element 515 may be a microstrip line that is connected to the first wire 513 and the second wire 514 in parallel. The circuit element 515 may be implemented in an empty space of a semiconductor package, and one end of the circuit element 515 may be connected to an equipotential terminal supplying a GND voltage.

One end of the first wire 513 may be connected to the IC pad 512 and the other end of the first wire 513 may be connected to the circuit element 515. One end of the second wire 514 may be connected to the package pad 511 and the other end of the second wire 514 may be connected to the circuit element 515.

FIG. 5B is a diagram illustrating an equivalent circuit between the package pad and the IC pad of the semiconductor package according to the fourth embodiment.

FIG. 5B may be an equivalent circuit 500 showing a configuration between the package pad 511 and the IC pad 512 described with reference to FIG. 5A. Referring to FIG. 5B, the equivalent circuit 500 may include the first parasitic component model W1, the second parasitic component model W2, and a microstrip line ML. An IC pad 520 may correspond to the IC pad 512 of FIG. 5A, a package pad 525 may correspond to the package pad 511 of FIG. 5A, and the microstrip line ML may correspond to the circuit element 515 of FIG. 5A.

The first parasitic component model W1 may represent a parasitic component generated due to the first wire 513 of FIG. 5A. The first parasitic component model W1 may include a parasitic capacitance C1 and the parasitic inductor L1 that are connected to each other. The second parasitic component model W2 may represent a parasitic component generated due to the second wire 514 of FIG. 5A. The second parasitic component model W2 may include a parasitic capacitance C2 and the parasitic inductor L2 that are connected to each other. One end of the microstrip line ML may be connected to the parasitic inductor L1 and the parasitic inductor L2 and the other end of the microstrip line ML may be connected to an equipotential terminal supplying a power supply voltage. For example, the other end of the microstrip line ML may be connected to an equipotential terminal supplying a GND voltage.

An RF signal may be transmitted from the IC pad 520 to the package pad 525. As the RF signal is transmitted from the IC pad 520 to the package pad 525, an impedance value from the viewpoint of the package pad 525 may change. The change of the impedance value due to the transmission of the RF signal is described in detail with reference to FIG. 5C.

FIG. 5C illustrates a Smith chart for describing an impedance from the viewpoint of the package pad of the semiconductor package according to the fourth embodiment.

FIG. 5C may be a diagram illustrating a Smith chart that shows a change of an impedance value due to the transmission of an RF signal on the circuit diagram of FIG. 5B, with a characteristic impedance value of “50” ohms. Referring to FIGS. 5B and 5C, an RF input impedance value at the IC pad 520 may be at the center circle of the Smith chart and match to “50” ohms. The impedance value at the center of the Smith chart may change into the impedance value at a first location 531 due to the parasitic capacitance C1. The impedance value at the first location 531 may change into the impedance value at a second location 532 due to the parasitic inductor L1. The impedance value at the second location 532 may change into the impedance value at a third location 533 due to the microstrip line ML. The impedance value at the third location 533 may change into the impedance value at a fourth location 534 due to the parasitic inductor L2. The impedance value at the fourth location 534 may change into the impedance value at a fifth location 535 due to the parasitic capacitance C2.

The impedance value at the fifth location 535 may correspond to an RF output impedance value at the package pad 525. The impedance value at the fifth location 535 may be substantially almost the same as the RF input impedance value at the IC pad 520. Thus, the RF input impedance value at the IC pad 520 and the RF output impedance value at the package pad 525 may be substantially almost the same.

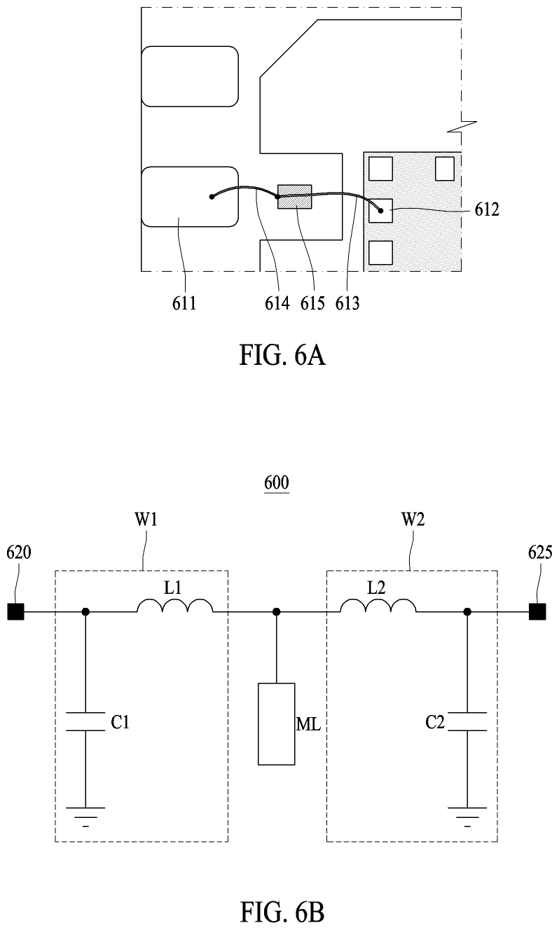

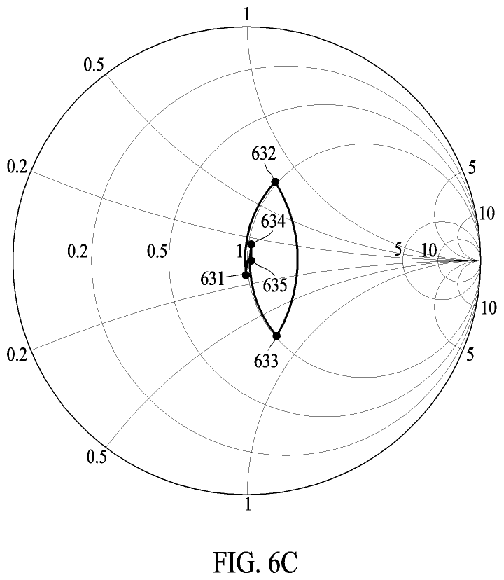

FIG. 6A is a diagram illustrating a connection relationship between a package pad and an IC pad of a semiconductor package according to a fifth embodiment.

FIG. 6A may be a diagram illustrating part of the semiconductor package 100 described above with reference to FIG. 1. Referring to FIG. 6A, a package pad 611 and an IC pad 612 may be connected through a first wire 613, a second wire 614, and a circuit element (or a passive element) 615. The circuit element 615 may be a microstrip line that is connected to the first wire 613 and the second wire 614 in parallel. The connection relationship between the package pad 611, the IC pad 612, the first wire 613, the second wire 614, and the circuit element 615 may be similar to the embodiment described above with reference to FIG. 5A. Compared to FIG. 5A, in FIG. 6A, the circuit element 615 may not be connected to an equipotential terminal supplying a power supply voltage.

FIG. 6B is a diagram illustrating an equivalent circuit between the package pad and the IC pad of the semiconductor package according to the fifth embodiment.

FIG. 6B may be an equivalent circuit 600 showing a configuration between the package pad 611 and the IC pad 612 described with reference to FIG. 6A. Referring to FIG. 6B, the equivalent circuit 600 may include the first parasitic component model W1, the second parasitic component model W2, and a microstrip line ML. An IC pad 620 may correspond to the IC pad 612 of FIG. 6A, a package pad 625 may correspond to the package pad 611 of FIG. 6A, and the microstrip line ML may correspond to the circuit element 615 of FIG. 6A.

The circuit structure of FIG. 6B may be similar to the embodiment described above with reference to FIG. 5B. Compared to FIG. 5B, in FIG. 6B, the microstrip line ML may not be connected to an equipotential terminal supplying a power supply voltage.

An RF signal may be transmitted from the IC pad 620 to the package pad 625. As the RF signal is transmitted from the IC pad 620 to the package pad 625, an impedance value from the viewpoint of the package pad 625 may change. The change of the impedance value due to the transmission of the RF signal is described in detail with reference to FIG. 6C.

FIG. 6C illustrates a Smith chart for describing an impedance from the viewpoint of the package pad of the semiconductor package according to the fifth embodiment.

FIG. 6C may be a diagram illustrating a Smith chart that shows a change of an impedance value due to the transmission of an RF signal on the circuit diagram of FIG. 6B, with a characteristic impedance value of “50” ohms. Referring to FIGS. 6B and 6C, an RF input impedance value at the IC pad 620 may be at the center circle of the Smith chart and match to “50” ohms. The impedance value at the center of the Smith chart may change into the impedance value at a first location 631 due to the parasitic capacitance C1. The impedance value at the first location 631 may change into the impedance value at a second location 632 due to the parasitic inductor L1. The impedance value at the second location 632 may change into the impedance value at a third location 633 due to the microstrip line ML. The impedance value at the third location 633 may change into the impedance value at a fourth location 634 due to the parasitic inductor L2. The impedance value at the fourth location 634 may change into the impedance value at a fifth location 635 due to the parasitic capacitance C2.

The impedance value at the fifth location 635 may correspond to an RF output impedance value at the package pad 625. The impedance value at the fifth location 635 may be substantially almost the same as the RF input impedance value at the IC pad 620. Thus, the RF input impedance value at the IC pad 620 and the RF output impedance value at the package pad 625 may be substantially almost the same.

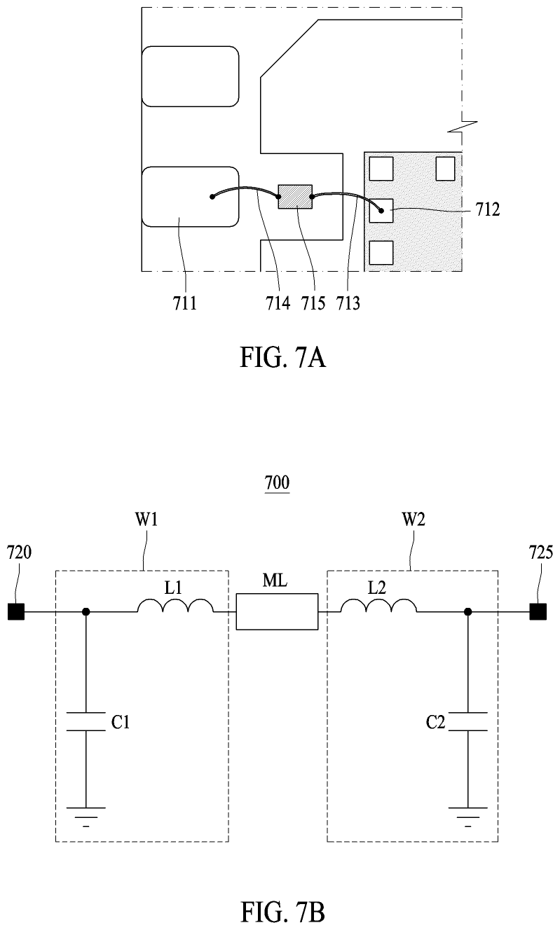

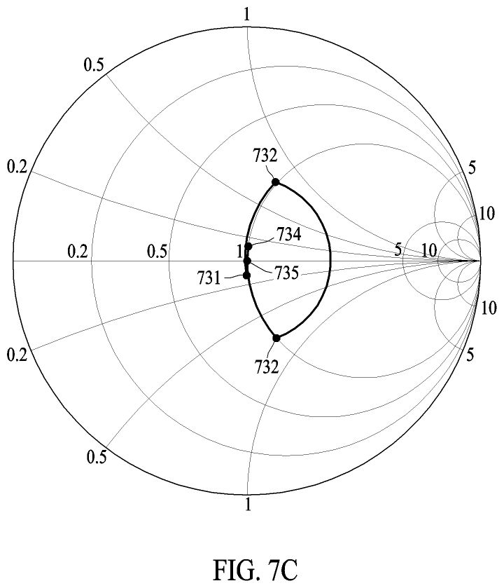

FIG. 7A is a diagram illustrating a connection relationship between a package pad and an IC pad of a semiconductor package according to a sixth embodiment.

FIG. 7A may be a diagram illustrating part of the semiconductor package 100 described above with reference to FIG. 1. Referring to FIG. 7A, a package pad 711 and an IC pad 712 may be connected through a first wire 713, a second wire 714, and a circuit element (or a passive element) 715. The circuit element 715 may be a microstrip line that is connected to the first wire 713 and the second wire 714 in series. The circuit element 715 may be implemented in an empty space of a semiconductor package.

One end of the first wire 713 may be connected to the IC pad 712 and the other end of the first wire 713 may be connected to the circuit element 715. One end of the second wire 714 may be connected to the package pad 711 and the other end of the second wire 714 may be connected to the circuit element 715.

FIG. 7B is a diagram illustrating an equivalent circuit between the package pad and the IC pad of the semiconductor package according to the sixth embodiment.

FIG. 7B may be an equivalent circuit 700 showing a configuration between the package pad 711 and the IC pad 712 described with reference to FIG. 7A. Referring to FIG. 7B, the equivalent circuit 700 may include the first parasitic component model W1, the second parasitic component model W2, and a microstrip line ML. An IC pad 720 may correspond to the IC pad 712 of FIG. 7A, a package pad 725 may correspond to the package pad 711 of FIG. 7A, and the microstrip line ML may correspond to the circuit element 715 of FIG. 7A.

The first parasitic component model W1 may represent a parasitic component generated due to the first wire 713 of FIG. 7A. The first parasitic component model W1 may include a parasitic capacitance C1 and the parasitic inductor L1 that are connected to each other. The second parasitic component model W2 may represent a parasitic component generated due to the second wire 714 of FIG. 7A. The second parasitic component model W2 may include a parasitic capacitance C2 and the parasitic inductor L2 that are connected to each other. One end of the microstrip line ML may be connected to the parasitic inductor L1 and the other end of the microstrip line ML may be connected to the parasitic inductor L2.

An RF signal may be transmitted from the IC pad 720 to the package pad 725. As the RF signal is transmitted from the IC pad 720 to the package pad 725, an impedance value from the viewpoint of the package pad 725 may change. The change of the impedance value due to the transmission of the RF signal is described in detail with reference to FIG. 7C.

FIG. 7C illustrates a Smith chart for describing an impedance from the viewpoint of the package pad of the semiconductor package according to the sixth embodiment.

FIG. 7C may be a diagram illustrating a Smith chart that shows a change of an impedance value due to the transmission of an RF signal on the circuit diagram of FIG. 7B, with a characteristic impedance value of “50” ohms. Referring to FIGS. 7B and 7C, an RF input impedance value at the IC pad 720 may be at the center circle of the Smith chart and match to “50” ohms. The impedance value at the center of the Smith chart may change into the impedance value at a first location 731 due to the parasitic capacitance C1. The impedance value at the first location 731 may change into the impedance value at a second location 732 due to the parasitic inductor L1. The impedance value at the second location 732 may change into the impedance value at a third location 733 due to the capacitor C3. The impedance value at the third location 733 may change into the impedance value at a fourth location 734 due to the parasitic inductor L2. The impedance value at the fourth location 734 may change into the impedance value at a fifth location 735 due to the parasitic capacitance C2.

The impedance value at the fifth location 735 may correspond to an RF output impedance value at the package pad 725. The impedance value at the fifth location 735 may be substantially almost the same as the RF input impedance value at the IC pad 720. Thus, the RF input impedance value at the IC pad 720 and the RF output impedance value at the package pad 725 may be substantially almost the same.

The components described in the embodiments may be implemented by hardware components including, for example, at least one digital signal processor (DSP), a processor, a controller, an application-specific integrated circuit (ASIC), a programmable logic element, such as a field programmable gate array (FPGA), other electronic devices, or combinations thereof. At least some of the functions or the processes described in the embodiments may be implemented by software, and the software may be recorded on a recording medium. The components, the functions, and the processes described in the embodiments may be implemented by a combination of hardware and software.

The scope of the present disclosure is defined not by the detailed description or the accompanying drawings but by the claims. Therefore, it is intended that various replacements, modifications, and changes may be made by one of ordinary skill in the art without departing from the technical spirit of the present disclosure described in the claims, and these are also covered within the scope of the present disclosure.

What is claimed is:

1. A semiconductor package comprising:
a semiconductor chip comprising an integrated circuit (IC) pad configured to output a wireless frequency signal;
a lead frame comprising a package pad configured to receive the wireless frequency signal;
a first wire of which one end is connected to the IC pad;
a second wire of which one end is connected to the package pad; and
a circuit element connected to the first wire and the second wire in parallel or in series,
wherein a radio frequency (RF) output impedance of the package pad or an RF output impedance of the IC pad is controlled by a type of the circuit element or a connection relationship between the circuit element, the first wire, and the second wire.

2. The semiconductor package of claim 1, wherein the circuit element is a capacitor connected to the first wire and the second wire in parallel.

3. The semiconductor package of claim 1, wherein the circuit element is a capacitor connected to the first wire and the second wire in series.

4. The semiconductor package of claim 1, wherein the circuit element is a resistance element connected to the first wire and the second wire in parallel.

5. The semiconductor package of claim 1, wherein the circuit element is a microstrip line connected to the first wire and the second wire in parallel.

6. The semiconductor package of claim 5, wherein the microstrip line is connected to an equipotential terminal supplying a power supply voltage.

7. The semiconductor package of claim 5, wherein the microstrip line is not connected to an equipotential terminal supplying a power supply voltage.

8. The semiconductor package of claim 1, wherein the circuit element is a microstrip line connected to the first wire and the second wire in series.

9. A semiconductor package comprising:
a semiconductor chip comprising an integrated circuit (IC) pad configured to output a wireless frequency signal;
a lead frame comprising a package pad configured to receive the wireless frequency signal;
a passive element placed between the IC pad and the package pad;
a first wire of which one end is connected to the IC pad and the other end is connected to the passive element; and
a second wire of which one end is connected to the package pad and the other end is connected to the passive element.

10. The semiconductor package of claim 9, wherein the passive element is a capacitor connected to the first wire and the second wire in parallel.

11. The semiconductor package of claim 9, wherein the passive element is a capacitor connected to the first wire and the second wire in series.

12. The semiconductor package of claim 9, wherein the passive element is a resistance element connected to the first wire and the second wire in parallel.

13. The semiconductor package of claim 9, wherein the passive element is a microstrip line connected to the first wire and the second wire in parallel.

14. The semiconductor package of claim 13, wherein the microstrip line is connected to an equipotential terminal supplying a power supply voltage.

15. The semiconductor package of claim 13, wherein the microstrip line is not connected to an equipotential terminal supplying a power supply voltage.

16. The semiconductor package of claim 9, wherein the passive element is a microstrip line connected to the first wire and the second wire in series.
